(19) United States
(12) Patent Application Publication
(10) Pub. No.: US 2011/0192445 A1
(43) Pub. Date: Aug. 11, 2011

(54) HIGH PRECISION, HIGH SPEED SOLAR CELL ARRANGEMENT TO A CONCENTRATOR LENS ARRAY AND METHODS OF MAKING THE SAME

(76) Inventors: Florian Solzbacher, Salt Lake City, UT (US); Erik Jung, Falkensee (DE)

(21) Appl. No.: 12/922,443

(22) PCT Filed: Mar. 13, 2009
(86) PCT No.: PCT/US09/37129

§ 371 Date: Dec. 6, 2010

Related U.S. Application Data
(60) Provisional application No. 61/036,305, filed on Mar. 13, 2008.

(51) Int. Cl. H01L 31/052; H01L 31/18

(52) U.S. Cl. 136/246; 438/65; 257/E31.127

(57) ABSTRACT

A method for fabricating a photoelectric array device with an optical micro lens array (10) using a plurality of photovoltaic dies (12) so a lens (14) is aligned to each die (12) in the array device. A back surface (16) of a lens array substrate (10) is metallized with electrical conducting lines and interconnects (18). Fabricated photovoltaic dies are aligned to an alignment substrate using a fluidic capillary-driven alignment process. The plurality of aligned dies (12) is attached mechanically and electrically to the metallized lens array substrate (10), so the each die (12) aligns with a lens (14) in the lens array substrate (10). The alignment substrate is removed from the dies (12) attached to the lens array substrate (10). A back panel substrate (22) is coupled mechanically and electrically to the plurality of dies (12) attached to the lens array substrate (10).

### RELATED APPLICATIONS

This application claims priority of U.S. Provisional Patent Application No. 61/036,305, filed Mar. 13, 2008, which is incorporated herein by reference.

### BACKGROUND

Solar cells can exhibit unique non-linear behavior with respect to electricity generation, if the solar power concentrated onto them is high enough. This means higher intensity light generates more electricity more efficiently than low intensity light. Also, solar cells work best with vertically incident light. Currently, solar cells are fabricated using circular wafers which are assembled into panels. This approach cannot benefit from a lens, as a) the required lens would be too large and b) the mechanical distance required cannot accommodate for a beam guiding according to the sun's position. Micro-lenses, and arrangement on the micro-scale, however, can overcome these issues. Placement of die-cut solar cell elements, however, is prohibitive for cost reasons. Activities have been reported to stretch a grid of singulated silicon dies (expandable or stretchable silicon targeting high efficiency solar cells by Stanford professor Peter Neumann (http://www.technologyreview.com/Nanotech/19901/)) to the pitch of a suitable microlens array (Bosch). However, neither approach has been demonstrated nor have interconnection schemes been identified. To our knowledge, the latter approach is also an issue with all other approaches trying to mount individual dies.

### BRIEF DESCRIPTION OF THE DRAWINGS

FIG. 1 is an example of a side view of the metallized optical micro lens array substrate, the plurality of photoelectric dies, and the back panel substrate that comprise the photoelectric array device in accordance with one embodiment of the present invention.

FIG. 2 is an example of a perspective view of the unassembled plurality of photoelectric dies on an alignment substrate unassembled to an optical micro lens array substrate in accordance with one embodiment of the present invention.

FIG. 3A-3D is an example of the Bohringer capillary-driven self-assembly process flow: FIG. 3A is a surface having hydrophobic areas and hydrophilic areas. FIG. 3B shows optional adhesive layer. FIG. 3C illustrates dies which are in proximity to the areas but are at non-equilibrium positions. FIG. 3D illustrates dies which are at surface energy minimum positions.

FIG. 4A is an example of a feature-directed self-assembly were each die has a single circular peg uniquely aligned with its receptor site having a circular trench.

FIG. 4B is a similar concept to FIG. 4A where each die has a circular peg and a cross peg uniquely aligned with its receptor site having a circular trench and across trench.

FIG. 5A is illustration of a process of floating hydrophobic sided dies where a tilted water surface is produced by orbital shaking.

FIG. 5B illustrates a force analysis of a die on the tilted water surface.

FIG. 6 is an example of palletized dies on an alignment substrate using a fluidic capillary-driven process of palletizing dies on an alignment substrate.

These drawings merely depict exemplary embodiments of the present invention they are, therefore, not to be considered limiting of its scope. It will be readily appreciated that the components of the present invention, as generally described and illustrated in the figures herein, could be arranged, sized, and designed in a wide variety of different configurations. Nonetheless, the invention will be described and explained with additional specificity and detail through the use of the accompanying drawings.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

It must be noted that, as used in this specification and the appended claims, the singular forms “a,” “an,” and “the” include plural referents unless the context clearly dictates otherwise. Thus, for example, reference to “a die” includes one or more of such features, reference to “layers” includes reference to one or more of such layers, and reference to “depositing” includes one or more of such steps.

Definitions

In describing and claiming the present invention, the following terminology will be used in accordance with the definitions set forth below.

As used herein, “substantial” when used in reference to a quantity or amount of a material, or a specific characteristic thereof, refers to an amount that is sufficient to provide an effect that the material or characteristic was intended to provide. Therefore, “substantially free” when used in reference to a quantity or amount of a material, or a specific characteristic thereof, refers to the absence of the material or characteristic, or to the presence of the material or characteristic in an amount that is insufficient to impart a measurable effect, normally imparted by such material or characteristic.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 0.6 mm to about 0.3 mm” should be interpreted to include not only the explicitly recited values of about 0.6 mm and about 0.3 mm, but also include individual values and sub-ranges within the indicated range. Thus, included in this numerical range are individual values such as 0.4 mm and 0.5, and sub-ranges such as from 0.5-0.4 mm, from 0.4-0.35, etc. This same principle applies to ranges reciting only one numerical value. Furthermore, such an interpretation should apply regardless of the breadth of the range or the characteristics being described.

As used herein, the term “about” means that dimensions, sizes, formulations, parameters, shapes and other quantities and characteristics are not and need not be exact, but may be approximated and/or larger or smaller, as desired, reflecting tolerances, conversion factors, rounding off, measurement error and the like and other factors known to those of skill in the art. Further, unless otherwise stated, the term “about” shall expressly include “exactly,” consistent with the discussion above regarding ranges and numerical data.

In the present disclosure, the term “preferably” or “preferred” is non-exclusive where it is intended to mean “preferably, but not limited to.” Any steps recited in any method or process claims may be executed in any order and are not limited to the order presented in the claims. Means-plus-function or step-plus-function limitations will only be employed where for a specific claim limitation all of the following conditions are present in that limitation: a) “means for” or “step for” is expressly recited; and b) a corresponding function is expressly recited. The structure, material or acts that support the means-plus function are expressly recited in the description herein. Accordingly, the scope of the invention should be determined solely by the appended claims and their legal equivalents, rather than by the descriptions and examples given herein.

### Embodiments of the Invention

The methods involve: a) Fluidic guided self alignment of solar cells in a die-cut form to a representative position defined by photolithography on a re-usable substrate; b) mounting the solar cell chips to a lens array substrate with current conducting lines and interconnect pads to a bottom substrate; c) mounting the thus populated lens array onto a backpanel substrate with thick current conducting lines and receiving contacts for the interconnect pads as of step b).

First, the solar cells are covered and patterned in accordance with their standard fabrication process and receive a solderable metallization (e.g. nickel) on top. Suitable solar cells can be of any type, e.g. conventional silicon solar cells or newer designs such as, but not limited to, amorphous silicon cells, nanoparticle films, dye-sensitized solar cells, diamond-based solar cells, etc.

Second, the solar cells are suspended in a carrier liquid (e.g. water) and allowed to flow statistically over the patterned surface of the re-usable carrier substrate. The patterned surface provides a significant difference in free energy (e.g. by surface energy or mechanical attachment sites, as reported by K. Boehringer et. al.), allowing the solar cells to position themselves in a highly parallel, high precision manner. The fluidic guided self alignment process can use the process disclosed in J. Fang, S. Liang, K. Wang, X. Xiong, K. F. Bohringer, Self-Assembly of Flat Micro Components by Capillary Forces and Shape Recognition, 2nd Annual Conference on Foundations of Nanoscience: Selfassembled Architectures and Devices (FNANO), Snowbird, UT, Apr. 24-28, 2005 (http://www.ee.washington.edu/research/mems/publications/), which is hereby incorporated by reference in its entirety, hereinafter “Bohringer.”

After the positioning process is finished, the re-usable carrier is aligned to the metallized lens array. This lens array has received a metallization to connect the top side of the solar cells by high volume fabrication soldering process. After completion of the solder process, the re-usable carrier is removed and can be re-used.

The populated lens array with the solar cells is now aligned to the back panel substrate which has receiving cavities realized during the fabrication of the three layer substrate. The metallized bottom of the cavity as well as the receiving pads are solder clad. After positioning the populated lens array to the backplane substrate, again a reflow solder process is performed, attaching the solar cell backsides as well as the interconnect pads of the lens array with the backpanel substrate. Thus, all solar cells are front and backside connected, well aligned to the optical lens array and ready for mechanical/electrical assembly into a panel.

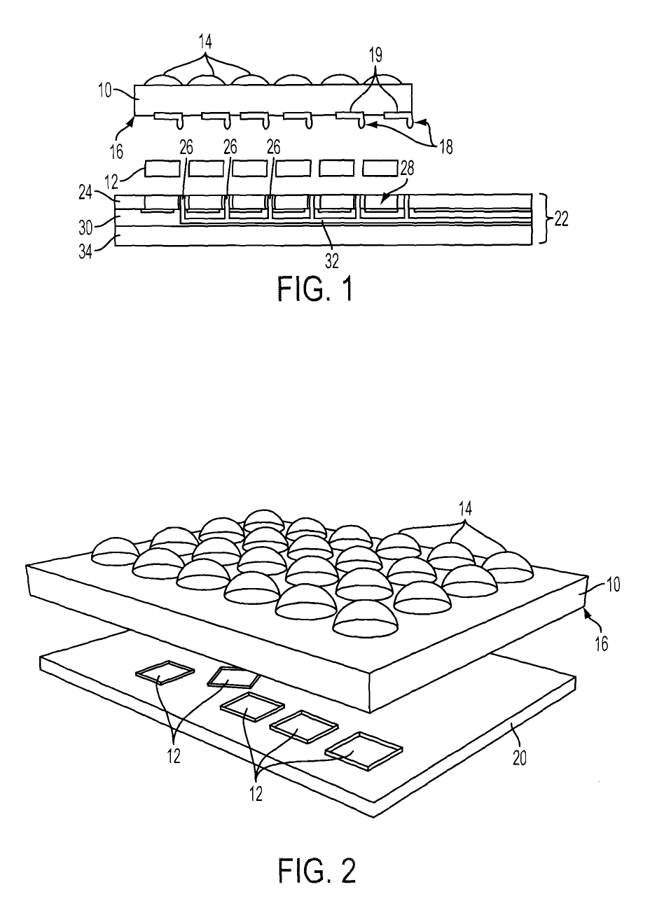

Referring now to FIG. 1, a photoelectric array device (shown in exploded view) can be fabricated with an optical micro lens array 10 using a plurality of photoelectric dies 12 so a lens 14 is aligned to each die in the array device. The term photoelectric can include photovoltaic cells and devices or solar cells. A back surface 16 of a lens array substrate can be metallized with electrical conducting lines and interconnects 18. The interconnects can optionally include metallized track features 19 which establish contact with the top-side of solar cell dies. Such designs are well known and can vary depending on the particular solar cell design, e.g. mesh, fingered, etc.

As shown generally in FIG. 2, fabricated photovoltaic dies 12 are aligned to an alignment substrate 20 using a fluidic capillary-driven alignment process. The plurality of aligned dies is attached mechanically and electrically to the back surface 16 of the metallized lens array substrate 10, so each die aligns with a lens 14 in the lens array substrate. The alignment substrate can be removed from the dies attached to the lens array substrate.

The lens array and die assembly can then be attached to a back panel substrate 22 as shown in FIG. 1. The back panel substrate can be coupled mechanically and electrically to the plurality of dies attached to the lens array substrate, so the dies are sandwiched between the lens array substrate and the back panel substrate. The coupling can be any suitable approach such as, but not limited to, bonding, vapor deposition, reflow bonding, some of which are described in more detail below. The back panel substrate can typically include electrical connections and/or mechanical support for integration into a full device. For example, FIG. 1 illustrates a back panel substrate having a top layer 24 with electrical contact pads 26 which align with interconnects 18. The top layer can also include receiving cavities 28 for the aligned dies 12. The back panel substrate can also include a middle layer 30 which has a structured contact plane 32 for electrically connecting contact pads 26. A optional bottom layer 34 can provide mechanical support and protection for the device. Other interconnect and backing layer designs can also be suitable as long as electrical connection with the dies is provided.

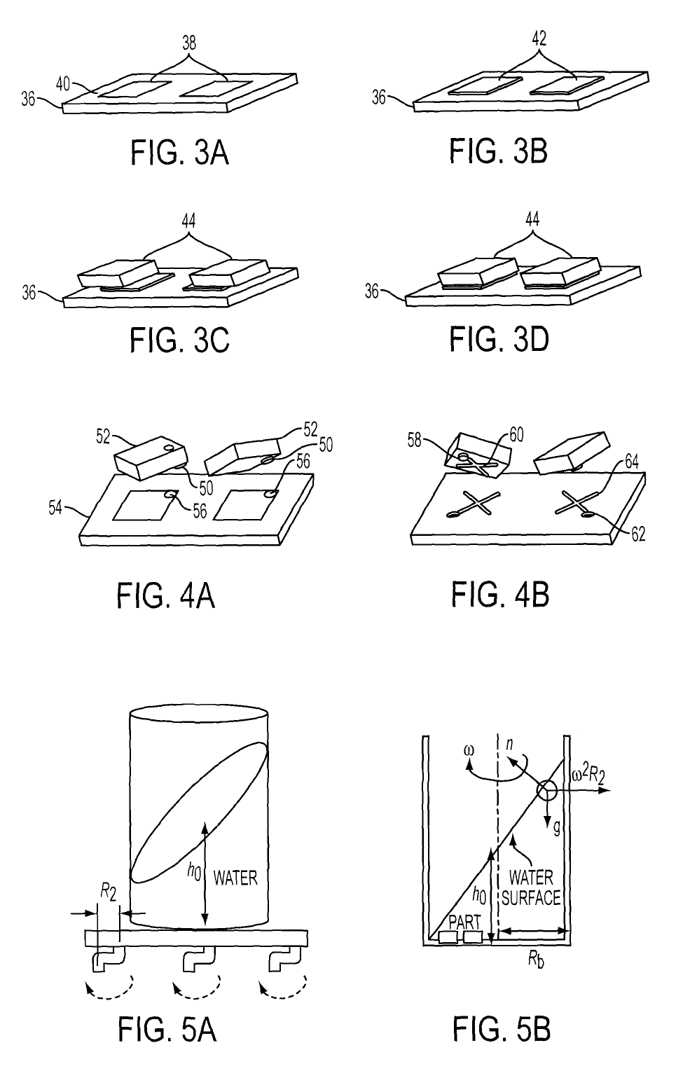

Using a fluidic capillary-driven alignment process to align the dies can involve various approaches. FIGS. 3A-3D illustrates one embodiment which uses photolithography to pattern a surface of the alignment substrate 36 to form a plurality of hydrophobic alignment areas 38 (called receptor sites). Each hydrophobic alignment area is sited to receive one of the dies. The remaining surface 40 of the alignment substrate is hydrophilic. FIG. 3B shows an optional adhesive liquid layer 42 which can facilitate adherence of the dies. The hydrophobic receptor site is enabled to receive a single die on the die's hydrophobic side which side is hydrophobic on the side opposite the light sensitive surface. FIG. 3C illustrates non-aligned dies 44. Due to the higher surface energy of these positions, the die migrate to an aligned position as shown in FIG. 3D.

In practice, the loose dies can be placed in a container with an aqueous carrier liquid. The container can be orbitally vibrated so the plurality of dies will float with a hydrophobic side facing away from the carrier liquid. The alignment substrate is vertically inserted into the carrier liquid. The hydrophobic side of the die will attract to the hydrophobic receptor site on the alignment substrate due to low interfacial energy or low surface energy and the dies will palletize or adhere to the alignment substrate so the dies are accurately aligned to the receptor sites which were patterned on the alignment substrate.

After all or a substantial majority of the receptor sites have adhered to a corresponding die, the alignment substrate is withdrawn from the carrier liquid. The hydrophobic side of the die stays firmly attached to the hydrophobic receptor sites of alignment substrate while the alignment substrate is removed from the carrier liquid. Residual carrier liquid can be removed from the dies and the carrier substrate with the alignment substrate has the dies on top when oriented in a nearly horizontal orientation. Generally, this fluidic alignment process can be accomplished using any materials having differential surface energies sufficient to align the parts. More specifically, at boundaries between solid, liquid and gas the respective boundary energy and contact angle defines whether a material wets or dewets. Although an aqueous carrier can be inexpensive and effective as described herein, other systems, e.g. non-aqueous, gaseous, etc. can also be suitable where boundary energies are differentially controlled to achieve the desired alignment.

In the aqueous carrier alignment embodiment, the hydrophobic side of the dies and the hydrophobic alignment areas or receptor sites can use Self Assembled Monolayer (SAM) materials. SAM materials can be, but are not limited to, thiolated Au, thioles, organo-(fluoro/chloro)-silanes like FOTS, FOMMS, or dodecylmonophosphate. The remaining surface on the alignment template can be rendered hydrophilic, e.g. using SiO₂ although other materials can also be suitable. To achieve the desired hydrophobic and hydrophilic properties on the dies and alignment template, the surfaces of the dies and alignment template coated with the hydrophobic and hydrophilic materials or the dies and alignment template can be fabricated with compounds using the hydrophobic and hydrophilic materials so the materials are embedded in the dies and alignment template, respectively.

The residual carrier liquid can be removed or dried using heat to evaporate a substantial portion of the residual carrier liquid. The residual carrier liquid can also be removed without heat using dry air with less than 20% humidity or a dry gas which will accelerate the evaporation process.

Since a rectangular (not square) die positions itself to the alignment template so interfacial surface energy is at a minimum, the die also have a minimal interfacial surface energy in a position rotated 180 degrees from another interfacial surface energy minimum position on the surface of the alignment substrate. These two interfacial surface energy minimum positions are due to the symmetry of the rectangular shape, so a rectangular shape may not uniquely align in a single position on a 360 degree rotation. Likewise, a square die has four positions where the interfacial surface energy is at a minimum, the positions being rotated 90 degrees from each other. The interconnecting contacts on the die can not align with the contacts on the lens array substrate or the back panel substrate if the die is not rotationally aligned, thus making the die non-functional because the contacts are not electrically coupled.

Uniquely rotationally aligning of the dies to the reusable lens array substrate can be achieved using non-symmetrical recessions on the periphery of the each lens of the lens array substrate which matches a complementary protrusion on the light sensitive surface of each die. The die can be placed on the lens array substrate so the light sensitive side of the die is facing down on the lens array substrate. The lens array substrate can be orbitally vibrated enabling the dies to rotate on the surface of the lens array substrate, so the unique protrusion on the die can recess into the unique corresponding recession in the lens array substrate. The lens array substrate can have a larger area shallow recession in the lens array substrate which prevents the die from leaving a particular lens area on the lens array while the die is rotating into a unique alignment position. FIG. 4A illustrates a circular protrusion on the die 52 which is a peg 50 on one corner of the die. The array substrate 54 includes a complimentary hole 56 for each peg so the die is uniquely aligned when the peg is in the corresponding hole. Other complimentary shapes can also be suitable such as trench, recession, or depression. FIG. 4B illustrates a circular peg 58 and cross peg 60 and complimentary circular trench 62 and cross trench 64, respectively. FIG. 5A illustrates a container having dies in the bottom which is orbitally shaken. A higher shaking speed will increase the water surface slope until dies at the bottom are exposed to air such that surface tension with the dies pulls them to the surface. Such dies collect at the surface and FIG. 5B illustrates the forces experienced at the water surface by floating dies.

In another embodiment, the rectangular shaped die can contain symmetrical redundant interconnect contacts, so the interconnect contacts will make electrical contact to the lens array contacts even when the die is rotated 180 degrees on the surface of the alignment substrate from another aligned position where the interfacial surface energy between the die and receptor site is at a minimum. With the redundant interconnect contacts symmetrical to the normal interconnect contacts on the same side of each of the dies, the dies will be electrically coupled to the lens array substrate and back panel substrate in either aligned position where the interfacial surface energy is at a minimum.

In another configuration, the lens array substrate and back panel can contain symmetrical redundant interconnect contacts (instead of symmetrical redundant interconnect contacts on the rectangular die), so the interconnect contacts will make electrical contact to the lens array contacts even when the die is rotated 180 degrees on the surface of the alignment substrate from another aligned position where the interfacial surface energy between the die and receptor site is at a minimum.

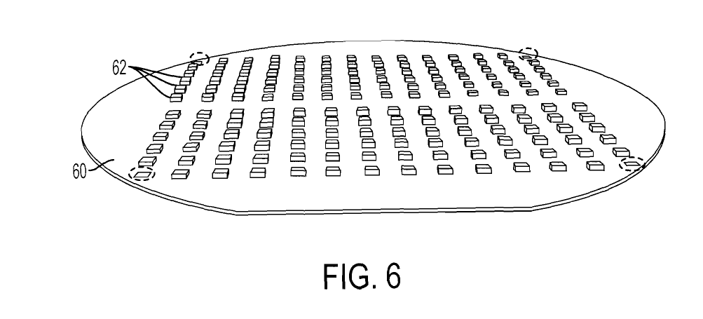

Although the above figures are limited to two or only a few dies, the above process is particularly suited to larger scale alignment of dozens or hundreds of dies on a single substrate, e.g. wafer. FIG. 6 illustrates a single silicon wafer 60 having 164 dies 62 aligned thereon. Note that the alignment is not always perfect as some minor variation (e.g. typically less than about 0.5 μm) can occur.

The dies can be metallized with solderable metallization on the light sensitive side of each die prior to aligning the photoelectric dies to the alignment substrate. Metallizing the dies can use nickel, copper, TiW—Pt, NiV, CrCu, Ni—P, or other suitable conductive materials. Nickel, especially Ni—P, can be deposited electrolessly without additional masking and lithography processes.

The dies can be electrically coupled and mechanically attached to the lens array substrate and back panel substrate using a reflow solder process. The electrically connection and mechanically attachment can also use adhesive bonding with conductive adhesive materials, sinter-bonding where a plurality of intermiscible metals are diffused under pressure and temperature without melting the intermiscible metals, or mechanical contacting wherein the lens array substrate and the back panel substrate are stabilized and maintained by applying pressure to the lens array substrate and the back panel substrate.

The back surface of the lens array substrate can be metallized using a redistribution layer process. The redistribution layer process can include the following steps: A seed metal layer can be sputter deposited on the back surface of the lens array substrate. A photoresist process can be used to pattern conducting lines. The photoresist process deposits photoresist on the back surface, develops the photoresist in a predetermined pattern using light, removes the undeveloped (or developed) leaving the developed (or undeveloped) photoresist on the back surface, etches back the seed layer of metal not protected by the photoresist, and removes the remaining photoresist exposing patterned conducting lines. Then, the seed metal layer can be reinforced with addition metal forming the conducting lines.

Another process that can be used to metallizing the back surface of the lens array substrate can use a laminated transparent dielectric substrate with pre-fabricated conducting lines within the transparent dielectric substrate. The pre-fabricated conducting lines can be created using photolithography and encased in a transparent dielectric substrate. Interconnect contacts can penetrate the transparent dielectric substrate surface adjoining the dies so the contacts can be coupled to the dies. A laser can be used to define the interconnect contacts or access point in the transparent dielectric substrate. The transparent substrate can use polyurethane, high temp polyurethane, polycarbonate, acryl, polysulfone, cycloolefinic-copolymers, or polypropylene materials.

The back surface of the lens array substrate can also be metallized using a Molded Interconnect Device (MID) process. MID can be used to fabricate the conductors and lens geometries. The molded interconnect device process can include the following steps: Patterning conducting lines on the back surface of the optical lens array substrate using a laser to create microscopically irregular surface ablations to enable a metal to adhere to the optical lens array substrate. Then, the back surface of the optical lens array substrate is bathed in a metal bath allowing a metal to precipitate in the ablations forming conducting lines.

The back panel substrate 22 can be fabricated with at least three layers as shown in FIG. 1. The back panel substrate can also contain receiving cavities for the dies enabling the back panel substrate to make direct contact on the lens array substrate, so the dies are sandwiched and encased within the lens array substrate and the back panel.

The method for fabricating a photoelectric array device with an optical micro lens array using a plurality of photoelectric dies can also include the step of mechanically adhering and electrically coupling a plurality of photoelectric array devices onto a panel substrate to form a solar panel.

The method described can form a photovoltaic array device with an optical micro lens array. The photovoltaic array device includes a metallized optical lens array substrate, a plurality of fabricated photoelectric dies, and a back panel substrate. The metallized optical lens array substrate with electrical conducting lines and a plurality of interconnect contacts includes a plurality of lens. The plurality of fabricated photoelectric dies is aligned to the lens array substrate. A plurality of interconnect contacts on a light sensitive side of each die is electrically coupling to the plurality of interconnect contacts on a back surface of the lens array substrate, which also mechanically attaches a die to each lens in lens array substrate. The back panel substrate is aligned and electrically coupled to the photoelectric dies attached to the lens array substrate, so a side opposite to the light sensitive side of each die is mechanically attached to the back panel substrate.

Another embodiment of a method for fabricating a photoelectric array device with an optical micro lens array using a plurality of photoelectric dies so a lens is aligned to each die in the array device can electrically couple a lens array substrate directly to a back panel substrate. A back surface of the lens array substrate is metallized with electrical conducting lines and interconnects. Fabricated photovoltaic dies are aligned to an alignment substrate using a fluidic capillary-driven alignment process. The plurality of aligned dies is attached mechanically and electrically to a back surface of the metallized lens array substrate, so each die aligns with a lens in the lens array substrate. The alignment substrate is removed from the dies attached to the lens array substrate. A back panel substrate is mechanically and electrically coupled to a plurality interconnect contacts of the lens array substrate.

The method described can form a photovoltaic array device with an optical micro lens array. The photovoltaic array device includes a metallized optical lens array substrate, a plurality of fabricated photoelectric dies, and a back panel substrate. A metallized optical lens array substrate with electrical conducting lines and a plurality of interconnect contacts includes a plurality of lens. A plurality of fabricated photoelectric dies is aligned to the lens array substrate. A plurality of interconnect contacts on a light sensitive side of each die is electrically coupling to the plurality of interconnect contacts on a back surface of the lens array substrate, which also mechanically attaches a die to each lens in lens array substrate. A plurality of interconnect contacts on a back panel substrate is aligned and electrically coupled directly to the plurality of interconnect contacts on the lens array substrate.

The present system and method has many advantages over the current method of fabricating solar cells. Using a micro lens array allows high intensity light which is more efficient in generating electricity to track the solar beams passively. Using individual dies to capture the focused light under lens creates a significant cost savings of reducing semiconductor material from non-illuminated areas under the micro lens array, while still generating a substantially similar quantity of electricity. Using smaller individual dies instead of a larger continuous semiconductor substrate or wafer gives the semiconductor material a greater power density. The micro lens focused on the individual dies reduces the amount of wasted semiconductor on non-illuminated areas. The fluidic assembly process eliminates the costly pick and place procedure for aligning and placing solar cell dies on the micro lens array. The fluidic assembly process uses a batch process versus a per unit process like the pick and place procedure, so the time required to perform the process is not governed by the number of parts. Using reflow soldering provides highly manufacturable and cost effective solution for attaching dies to micro lens array and a back panel. A panel to panel assembly provides high parallelity of processing, lowering fabrication cost significantly.

It is to be understood that the above-referenced arrangements are illustrative of the application for the principles of the present invention. Numerous modifications and alternative arrangements can be devised without departing from the spirit and scope of the present invention while the present invention has been shown in the drawings and described above in connection with the exemplary embodiment(s) of the invention. It will be apparent to those of ordinary skill in the art that numerous modifications can be made without departing from the principles and concepts of the invention as set forth in the claims.

What is claimed is:

1. A method for fabricating a photoelectric array device with an optical lens array, comprising the steps of:
metallizing a back surface of an optical lens array substrate with electrical conducting lines and interconnect contacts, wherein said lens array substrate includes a plurality of lenses;
aligning a plurality of fabricated photoelectric dies to an alignment substrate using a fluidic capillary-driven alignment process, wherein a light sensitive side of each die is opposite a surface of the die in contact with the alignment substrate;
mechanically and electrically attaching the plurality of dies to the lens array substrate, wherein each die is aligned to a back surface of one of the plurality of lenses in the lens array substrate and electrically coupled to a plurality of interconnect contacts;
removing the alignment substrate from the dies attached to the lens array substrate;
mechanically and electrically coupling a back panel substrate with electrical conducting lines to the plurality of dies attached to the lens array substrate, wherein each die is aligned to a plurality of interconnect contacts on the back panel substrate.

2. The method of claim 1, wherein the aligning a plurality of fabricated photoelectric dies to the alignment substrate further comprises the steps of:
patterning a surface of the alignment substrate to form a plurality of hydrophobic alignment areas each sited to receive one of the dies called a plurality of receptor sites wherein a remaining surface of the alignment substrate is hydrophilic, wherein each receptor site is enabled to receive a single hydrophobic side opposite the light sensitive surface of a corresponding die;
placing a plurality of loose dies in a container with a carrier liquid;
orbitally vibrating the container so the plurality of dies will float with a hydrophobic side facing away from the carrier liquid;
palletizing the dies to the alignment substrate by inserting the alignment substrate into the carrier liquid, wherein a low interfacial energy between the hydrophobic side of a die surface and the receptor sites of the alignment substrate aligns and adheres the hydrophobic side of the die surface to the receptor sites;
withdrawing the alignment substrate from the carrier liquid with the hydrophobic side of the die firmly attached to the hydrophobic side of alignment substrate; and
removing a residual carrier liquid from the dies and the carrier substrate while the alignment substrate is in a horizontal orientation with the dies on top.

3. The method of claim 2, wherein the hydrophobic side of the die and the hydrophobic alignment areas comprise a self assembled monolayer material, and the remaining hydrophilic surface comprises SiO₂.

4. The method of claim 3, wherein a hydrophobization with the self assembled monolayer material of the hydrophobic side and the hydrophobic alignment areas is selected from the group consisting of a thiolated Au, a thiole, an organofluorosilane, an organochlorosilane, and combinations thereof.

5. The method of claim 4, wherein the organofluorosilane is selected from the group consisting of a FOTS, a FOMMS, a dodecylmonophosphate, and combinations thereof.

6. The method of claim 1, wherein the attaching the photoelectric dies to the lens array substrate includes rotationally aligning the dies to the lens array substrate, wherein the lens array substrate contains non-symmetrical recessions on the periphery of the each lens and which recession matches a complementary protrusion on the light sensitive surface of each die, so the die are uniquely rotatably aligned to the surface of the optical lens array substrate.

7. The method of claim 1, wherein the photoelectric dies have a substantially rectangular shape with a symmetrical redundant interconnect contacts, wherein the dies will be aligned and will be electrically coupled to the lens array substrate and back panel substrate when rotated 180 degrees on the alignment substrate from dies position where a interfacial surface energy between the die and the receptor sites on the alignment substrate is at a substantial minimum.

8. The method of claim 1, wherein the photoelectric dies have a substantially rectangular shape and the lens array substrate and the back panel substrate have a symmetrical redundant interconnect contacts, wherein the dies will be aligned and will be electrically coupled to the lens array substrate and the back panel substrate when rotated 180 degrees on the alignment substrate from a dies position where a interfacial surface energy between the die and the receptor sites on the alignment substrate is at a substantial minimum.

9. The method of claim 1, further comprising the step of metallizing the dies with solderable metallization on the light sensitive side of each die prior to aligning photoelectric dies to the alignment substrate.

10. The method of claim 9, wherein the metallizing the dies uses a metal selected from the group consisting of nickel, copper, TiW—Pt, NiV, CrCu, Ni—P, and combinations thereof.

11. The method of claim 1, wherein the attaching the plurality of dies to the lens array substrate uses a reflow solder process.

12. The method of claim 1, wherein the attaching the plurality of dies to the lens array substrate uses a process selected from the group consisting of adhesive bonding with conductive adhesive materials, sinter-bonding wherein a plurality of intermiscible metals are diffused under pressure and temperature without melting the intermiscible metals, and mechanical contacting wherein the lens array substrate is stabilized and maintained by applying pressure to the lens array substrate.

13. The method of claim 1, wherein the coupling the back panel substrate to the plurality of dies uses a reflow solder process.

14. The method of claim 1, wherein the coupling the back panel substrate to the plurality of dies uses a process selected from the group consisting of adhesive bonding with conductive adhesive materials, sinter-bonding wherein a plurality of intermiscible metals are diffused under pressure and temperature without melting the intermiscible metals, and mechanical contacting wherein the lens array substrate and the back panel substrate are stabilized and maintained by applying pressure to the lens array substrate and the back panel substrate.

15. The method of claim 1, wherein the metallizing the back surface of the lens array substrate uses a redistribution layer process.

16. The method of claim 1, wherein the metallizing the back surface of the lens array substrate further comprises:
sputter depositing a seed metal layer on the back surface of the optical lens array substrate;
patterning for conducting lines using a photoresist process; and
reinforcing the seed metal layer with addition metal forming the conducting lines.

17. The method of claim 1, the metallizing the back surface of the lens array substrate further comprises laminating a transparent dielectric substrate with pre-fabricated conducting lines within the transparent dielectric substrate and interconnect contacts penetrating the transparent dielectric substrate surface adjoining the dies.

18. The method of claim 17, wherein the transparent substrate uses a material selected from the group consisting of polyurethane, high temp polyurethane, polycarboate, acryl, polysulfone, cycloolefinic-copolymers, polypropylene, and combinations thereof.

19. The method of claim 1, wherein the metallizing the back surface of the lens array substrate further comprises a molded interconnect device process.

20. The method of claim 19, wherein molded interconnect device process comprises:
patterning conducting lines using a laser to create microscopically irregular surface ablations to enable a metal to adhere to the optical lens array substrate; and
bathing the back surface of the optical lens array substrate in a metal bath allowing a metal to precipitate in the ablations forming conducting lines.

21. The method of claim 1, wherein the back panel substrate comprises receiving cavities for the dies enabling the back panel substrate to directly contact the lens array substrate.

22. The method of claim 1, further comprising the step of adhering a plurality of photoelectric array devices onto a panel substrate mechanically and electrically to form a solar panel.

23. A photovoltaic array device with an optical lens array, comprising:
a metallized optical lens array substrate with electrical conducting lines and a plurality of interconnect contacts, wherein said lens array substrate includes a plurality of lenses;
a plurality of fabricated photoelectric dies aligned and electrically coupling a plurality of interconnect contacts on a light sensitive side of each die to the plurality of interconnect contacts on a back surface of the lens array substrate, wherein each die is mechanically attached to each lens in lens array substrate;
a back panel substrate aligned and electrically coupled to the photoelectric dies attached to the lens array substrate, wherein a side opposite to the light sensitive side of each die is mechanically attached to the back panel substrate.
